(19) United States
(12) Patent Application Publication
(10) Pub. No.: US 2026/0149418 A1
(43) Pub. Date: May 28, 2026

(54) POWER AMPLIFIER SYSTEMS BASED ON IN-PHASE POWER SYNTHESIS

(71) Applicant: ETRA SEMICONDUCTOR (SUZHOU) CO., LTD., Suzhou (CN)

(72) Inventors: Xinyu LIU, Suzhou (CN); Jun CHEN, Suzhou (CN)

(73) Assignee: ETRA SEMICONDUCTOR (SUZHOU) CO., LTD., Suzhou (CN)

(21) Appl. No.: 19/310,905

(22) Filed: Aug. 26, 2025

Related U.S. Application Data
(63) Continuation of application No. PCT/CN2024/138358, filed on Dec. 11, 2024.

(30) Foreign Application Priority Data
Nov. 22, 2024 (CN) 202411678875.7

(51) Int. Cl. H03F 1/56; H03F 3/21

(52) U.S. Cl. CPC H03F 1/56; H03F 3/211; H03F 2200/222; H03F 2200/451

(57) ABSTRACT

Provided is a power amplifier system based on in-phase power synthesis, including an input port; an output port; a plurality of power amplification branches, each of the plurality of power amplification branches is connected to the input port, the plurality of power amplification branches include at least one main power amplification branch and at least one auxiliary power amplification branch, each of the plurality of power amplification branches is configured to amplify an input signal of a same phase received from the input port; and an in-phase synthesizer is connected between the plurality of power amplification branches and the output port, the in-phase synthesizer is configured to perform power synthesis on the amplified signal at the same phase output from each of the plurality of power amplification branches to obtain a synthesized output signal, and transmit the synthesized output signal to the output port for output.

### CROSS-REFERENCE TO RELATED APPLICATIONS

This application is a Continuation of International Application No. PCT/CN2024/138358, filed on Dec. 11, 2024, which claims priority to Chinese Patent Application No. 202411678875.7, filed on Nov. 22, 2024, the entire contents of each of which are hereby incorporated by reference.

### TECHNICAL FIELD

The present disclosure relates to the field of radio frequency (RF) and microwave technology, and in particular relates to a power amplifier system based on in-phase power synthesis.

### BACKGROUND

From the first practical stage of radio communication technology to the current 5G mobile communication, communication technology has developed rapidly for over a hundred years. Whether it is the early radio communication technology, modern mobile communication technology, or current artificial intelligence and smart Internet of Things (IoT), no complex communication system can function without the most fundamental and essential device—a power amplifier. As the core component of a communication system, the performance of the power amplifier directly determines the signal propagation distance, signal propagation quality, and signal propagation bandwidth.

In 4G/5G communication systems, RF front-end power amplifier modules should be capable of delivering 32 dBm LTE linear power output (Maximum Power Reduction (MPR)=0) at lower supply voltages, i.e., generating 32 dBm linear power output according to the Long Term Evolution (LTE) wireless communication standard, where the Peak-to-Average Power Ratio (PAPR) of signals may reach as high as 4 dB. Under high data rate communication conditions, the PAPR may be considerably greater than 6 dB. In other cases, such as under WiFi7, the PAPR may be as high as 15 dB. As a result, the efficiency at power points with 6 dB or more output power back-off from saturation becomes particularly important for mobile terminal applications.

The industry is currently focused on improving back-off power efficiency from various key points in signal transmission branches. Techniques include Digital Pre-Distortion (DPD) techniques to optimize the input signal; power dynamic modulation techniques such as Envelope Tracking (ET) and Envelope Elimination and Recovery (EER) to optimize the operating state of the system; and techniques such as Doherty, Out-phasing, and LMBA to dynamically modulate the load. These techniques are designed with complex architectures that make it difficult to achieve broadband performance. Among these, the Doherty architecture, first proposed in 1936, remains widely used today.

However, the Doherty architecture requires dynamic modulation of the load based on a 90° phase relationship for signal synthesis. However, the presence of a 90° impedance conversion network within this architecture, combined with the parasitic impedance of the amplifiers themselves, presents significant challenges in extending its bandwidth beyond one octave.

### SUMMARY

To address this limitation, the present disclosure proposes a power amplifier based on in-phase power synthesis to solve the technical problem that it is difficult to extend the bandwidth of the existing architecture beyond one octave.

One or more embodiments of the present disclosure provide a power amplifier system based on in-phase power synthesis, the power amplifier system comprises: an input port, an output port, and a plurality of power amplification branches and an in-phase synthesizer disposed between the input port and the output port, wherein each of the plurality of power amplification branches is connected to the input port, the plurality of power amplification branches include at least one main power amplification branch and at least one auxiliary power amplification branch, each of the plurality of power amplification branches is configured to amplify an input signal of a same phase received from the input port to obtain an amplified signal; wherein when the at least one auxiliary power amplification branch is in an operating state, a load modulation is performed on the at least one main power amplification branch to reduce a load impedance of the at least one main power amplification branch; and the in-phase synthesizer is connected between the plurality of power amplification branches and the output port, the in-phase synthesizer is configured to perform power synthesis on the amplified signal at the same phase output from each of the plurality of power amplification branches to obtain a synthesized output signal, and transmit the synthesized output signal to the output port for output.

In some embodiments, each of the plurality of power amplification branches includes: a power amplification unit configured to amplify the input signal of the same phase received from the input port for one of the plurality of power amplification branches in which the power amplification unit is located; and an impedance conversion network connected to the power amplification unit, configured to perform the load modulation of the power amplification unit of one of the plurality of power amplification branches in which the impedance conversion network is located.

In some embodiments, a type of a power amplification unit used in the at least one main power amplification branch is different from a type of a power amplification unit used in the at least one auxiliary power amplification branch.

In some embodiments, when an output power of the power amplifier system is less than a first threshold, the at least one main power amplification branch is in the operating state, and the at least one auxiliary power amplification branch is in an off state.

In some embodiments, when the output power of the power amplifier system is not less than the first threshold, the at least one auxiliary power amplification branch is in the operating state.

In some embodiments, when the at least one auxiliary power amplification branch is in the operating state, the load modulation is performed on the at least one main power amplification branch to reduce the load impedance of the at least one main power amplification branch including: when the at least one auxiliary power amplification branch in the operating state, the at least one auxiliary power amplification branch performing the load modulation of the at least one main power amplification branch to reduce the load impedance of the at least one main power amplification branch until a difference between the load impedance of the at least one main power amplification branch and a load impedance of the at least one auxiliary power amplification branch is less than a second threshold.

In some embodiments, an initial load impedance of the at least one main power amplification branch is ZC, a count of the at least one auxiliary power amplification branch is N, and when the load impedance of the at least one main power amplification branch is reduced to be equal to the load impedance of the at least one auxiliary power amplification branch, the load impedance of the at least one main power amplification branch becomes ZC/(N+1).

In some embodiments, the impedance conversion network includes a first capacitor, a second capacitor, a first coupling line, and a second coupling line; wherein a first end of the first capacitor and a first end of the first coupling line are connected to a first input port of the impedance conversion network, and a first end of the second capacitor and a first end of the second coupling line are connected to a second input port of the impedance conversion network, respectively; and a second end of the second capacitor and a second end of the first coupling line are connected to a first output port of the impedance conversion network, and a second end of the first capacitor and a second end of the second coupling line are connected to a second output port of the impedance conversion network, respectively.

In some embodiments, the in-phase synthesizer includes a plurality of signal input ports, a signal output port, and M pairs of coupling lines connected between the plurality of signal input ports and the signal output port; wherein a positive input port and a negative input port of at least one of the plurality of signal input ports are connected to a positive coupling line and a negative coupling line of different pairs of coupling lines, respectively, and M is equal to a count of the plurality of power amplification branches.

In some embodiments, the plurality of signal input ports of the in-phase synthesizer are not isolated from each other.

In some embodiments, an isolation module is disposed between at least two of the plurality of signal input ports of the in-phase synthesizer.

In some embodiments, the in-phase synthesizer includes a plurality of signal input ports, a signal output port, and M pairs of coupling lines connected between the plurality of signal input ports and the signal output port; wherein a positive input port and a negative input port of each of the plurality of signal input ports are connected to a positive coupling line and a negative coupling line of a corresponding pair of coupling lines, respectively, and M is equal to a count of the plurality of power amplification branches.

In some embodiments, an isolation module is disposed between at least two of the plurality of signal input ports of the in-phase synthesizer.

In some embodiments, power amplifier system further comprises: an in-phase power divider connected between the input port and the plurality of power amplification branches, configured to perform power division on the input signal received from the input port to obtain a plurality of signals of the same phase before output.

In some embodiments, each of the plurality of power amplification branches further includes at least one of an input impedance matching circuit located on a signal input side of the power amplification unit or an output impedance matching circuit located on a signal output side of the power amplification unit.

Additional aspects and advantages of the present disclosure will be partially given in the following description, and partially will become apparent from the following description, or will be learned through the practice of the present application.

### BRIEF DESCRIPTION OF THE DRAWINGS

In order to more clearly illustrate the technical solutions in the embodiments of the present disclosure or in the prior art, the accompanying drawings that are required to be used in the embodiments will be briefly described below, and it is clear that the described embodiments are only a part of the embodiments, and that to those skilled in the art, other drawings can be obtained according to these drawings without creative labor.

FIG. 1 is an architectural diagram illustrating a power amplifier system based on in-phase power synthesis according to Embodiment 1 of the present disclosure;

FIG. 2 is a schematic diagram illustrating impedance variation with an operating state of the power amplifier system based on in-phase power synthesis according to Embodiment 1 of the present disclosure;

FIG. 3 is a schematic diagram illustrating simulation results of the power amplifier system based on in-phase power synthesis according to Embodiment 1 of the present disclosure;

FIG. 4 is a schematic diagram illustrating a circuit of an impedance conversion network according to Embodiment 1 of the present disclosure;

FIG. 5 is a schematic diagram illustrating a circuit of an in-phase synthesizer according to Embodiment 1 of the present disclosure;

FIG. 6 is another schematic diagram illustrating the circuit of the in-phase synthesizer according to Embodiment 1 of the present disclosure;

FIG. 7 is another architecture diagram illustrating the power amplifier system based on in-phase power synthesis according to Embodiment 1 of the present disclosure;

FIG. 8 is an architectural diagram illustrating a power amplifier system based on in-phase power synthesis according to Embodiment 2 of the present disclosure;

FIG. 9 is a schematic diagram illustrating simulation results of the power amplifier system based on in-phase power synthesis according to Embodiment 2 of the present disclosure;

FIG. 10 is a schematic diagram illustrating a circuit of an in-phase synthesizer according to Embodiment 2 of the present disclosure;

FIG. 11 is an architectural diagram illustrating a power amplifier system based on in-phase power synthesis according to Embodiment 3 of the present disclosure;

FIG. 12 is a schematic diagram illustrating simulation results of the power amplifier system based on in-phase power synthesis according to Embodiment 3 of the present disclosure;

FIG. 13 is a schematic diagram illustrating a circuit of an in-phase synthesizer according to Embodiment 3 of the present disclosure;

FIG. 14 is an architectural diagram illustrating a power amplifier system based on in-phase power synthesis according to Embodiment 4 of the present disclosure; and

FIG. 15 is a schematic diagram illustrating a circuit of an in-phase synthesizer according to Embodiment 4 of the present disclosure.

### DETAILED DESCRIPTION

To enable those skilled in the art to better understand the embodiments of the present disclosure, the technical solutions in the embodiments of the present disclosure are clearly and completely described below in conjunction with the accompanying drawings, and it is clear that the described embodiments are only a part of the embodiments, not all of the embodiments. Based on the embodiments in the present disclosure, all other embodiments obtained by those skilled in the art without creative labor should fall within the scope of protection of the present disclosure.

As described in the background, the current Doherty architecture requires dynamic modulation of the load based on a 90° phase relationship to achieve power synthesis of the signals. The presence of a 90° impedance conversion network within this architecture, combined with the parasitic impedance of the amplifiers themselves, presents significant challenges in extending its bandwidth beyond one octave.

Based on this, some embodiments of the present disclosure provide a power amplifier system based on in-phase power synthesis, including: an input port (e.g., RF Input), an output port (e.g., RF Output), and a plurality of power amplification branches (e.g., a plurality of power amplification branches 100) and an in-phase synthesizer (e.g., an in-phase synthesizer 200) disposed between the input port and the output port. Each of the plurality of power amplification branches is connected to the input port, and is configured to amplify an input signal of a same phase received from the input port to obtain an amplified signal. The plurality of power amplification branches include at least one main power amplification branch and at least one auxiliary power amplification branch, wherein when the at least one auxiliary power amplification branch is in an operating state, a load modulation is performed on the at least one main power amplification branch to reduce a load impedance of the at least one main power amplification branch. The in-phase synthesizer is connected between the plurality of power amplification branches and the output port, and is configured to perform power synthesis on the amplified signal at the same phase output from each of the plurality of power amplification branches to obtain a synthesized output signal, and transmit the synthesized output signal to the output port for output.

The power amplifier system based on in-phase power synthesis provided in the embodiments of the present disclosure (e.g., Embodiment 1, Embodiment 2, Embodiment 3, Embodiment 4, etc.) is able to get rid of the limitation of the bandwidth imposed by the 90° phase, and to realize that the signals outputted from the plurality of power amplification (PA) branches are power synthesized at the same phase, thus, a narrowband, octave or even 10-octave operating bandwidth may be achieved, thereby achieving a high fallback power efficiency.

The present disclosure will be specifically illustrated in the following by means of specific embodiments.

### Embodiment 1

FIG. 1 is an architectural diagram illustrating a power amplifier system based on in-phase power synthesis according to Embodiment 1 of the present disclosure. As shown in FIG. 1, the power amplifier system based on in-phase power synthesis may include: an input port (RF Input), an output port (RF Output), a plurality of power amplification branches 100, and an in-phase synthesizer 200. The plurality of power amplification branches 100 and the in-phase synthesizer 200 are connected between the input port (RF Input) and the output port (RF Output) in sequence.

Each of the plurality of power amplification branches 100 is connected to the input port (RF Input), and may receive an input signal from the input port (RF Input). It should be noted that in the embodiments of the present disclosure, the input signal received by each of the plurality of power amplification branches 100 may have the same phase. Each of the plurality of power amplification branches 100 is configured to amplify the input signal of the same phase received from the input port (RF Input) to obtain an amplified signal. That is, each of the plurality of power amplification branches 100 may amplify the input signal received by itself from the input port (RF Input) to obtain the amplified signal of the power amplification branch, so that the plurality of power amplification branches may obtain a plurality of amplified signals. The input signals received by the plurality of power amplification branches 100 from the input port (RF Input) have the same phase.

The in-phase synthesizer 200 is connected between the plurality of power amplification branches 100 and the output port (RF Output), and is configured to perform power synthesis on the amplified signal at the same phase output from each of the plurality of power amplification branches to obtain a synthesized output signal, and transmit the synthesized output signal to the output port (RF Output) for output.

In some embodiments, the plurality of power amplification branches 100 include at least one main power amplification branch 110 and at least one auxiliary power amplification branch 120. That is, the plurality of power amplification branches 100 use two or more power amplifiers, and by performing phase compensation between different branches, power synthesis of output signals from the plurality of power amplification branches at the same phase may be achieved.

In some embodiments, each of the plurality of power amplification branches 100 includes a power amplification unit and an impedance conversion network. The power amplification unit is configured to amplify the input signal of the same phase received from the input port (RF Input) for one of the plurality of power amplification branches in which the power amplification unit is located; the impedance conversion network is connected to the power amplification unit, and is configured to perform the load modulation of the power amplification unit of one of the plurality of power amplification branches in which the impedance conversion network is located.

In the embodiments of the present disclosure, the location relationship between the impedance conversion network and the power amplification unit is not specifically limited, and may be set according to the actual needs during the specific implementation. For example, in some specific embodiments, along a transmission direction of signals, the impedance conversion network is disposed in front of the power amplification unit, i.e., the impedance conversion network is disposed between the input port (RF Input) and the power amplification unit. In other specific embodiments, along the transmission direction of the signals, the impedance conversion network is disposed at the rear of the power amplification unit, i.e., the impedance conversion network is disposed between the power amplification unit and the output port (RF Output).

With further reference of FIG. 1, in some embodiments, the plurality of power amplification branches 100 includes one main power amplification branch 110 and one auxiliary power amplification branch 120. The main power amplification branch 110 may include a main power amplification unit 130a and a first impedance conversion network 140a; and the auxiliary power amplification branch 120 may include an auxiliary power amplification unit 130b and a second impedance conversion network 140b. The first impedance conversion network 140a is connected between the input port (RF Input) and the main power amplification unit 130a, and the second impedance conversion network 140b is connected between the auxiliary power amplification unit 130b and the output port (RF Output).

In some embodiments, the types of power amplification units used in the main power amplification branch and the auxiliary power amplification branch in the plurality of power amplification branches 100 are different. As shown in FIG. 1, the type of the power amplification unit used in the main power amplification branch 110 and the type of the power amplification unit used in the auxiliary power amplification branch 120 may be different, i.e., the type of the main power amplification unit 130a is different from the type of the auxiliary power amplification unit 130b.

The power amplification unit of the main power amplification branch (e.g., the main power amplification branch 110) may be kept on (i.e., in the operating state) at a low input power. The power amplification unit of the auxiliary power amplification branch (e.g., the auxiliary power amplification branch 120) may be in an off state at the low input power and driven by a high input power into a class C or class B state, also called Peaking PA.

The in-phase power synthesis of the power amplifier system provided in the embodiments of the present disclosure may be implemented through in-phase structures (e.g., a Wilkinson power divider and a 180° transformer synthesis structure) or 90° structures (e.g., a coupling line synthesis and a 90° hybrid couple synthesis structure) for designing the power amplification unit.

In some embodiments, types of the impedance conversion networks employed in the main power amplification branch and the auxiliary power amplification branch in the plurality of power amplification branches 100 may be the same or different, and the present disclosure does not make any specific limitations thereon, and the specific implementation may be set according to the actual product requirements. In conjunction with FIG. 1, in some specific embodiments, the impedance conversion networks of the main power amplification branch 110 and the auxiliary power amplification branch 120 may be the same or different, i.e., the first impedance conversion network 140a and the second impedance conversion network 140b may be the same or different. For example, the main power amplification branch 110 and the auxiliary power amplification branch 120 may use impedance conversion networks with the same phase offset, i.e., the first impedance conversion network 140a and the second impedance conversion network 140b have the same phase offset, so as to ensure that the phases of the amplified signals output from the main power amplification branch 110 and the auxiliary power amplification branch 120 are the same during power synthesis in the in-phase synthesizer 200.

In some embodiments, when the at least one auxiliary power amplification branch of the plurality of power amplification branches 100 is in the operating state, a load modulation is performed on the at least one main power amplification branch to reduce a load impedance of the at least one main power amplification branch. In some specific embodiments, both the main power amplification branch 110 and the auxiliary power amplification branch 120 are configured to amplify an input signal of a same phase received from the input port (RF Input), and the when the auxiliary power amplification branch 120 is in an operating state, the load modulation is performed on the main power amplification branch 110 to reduce the load impedance of the at least one main power amplification branch 110.

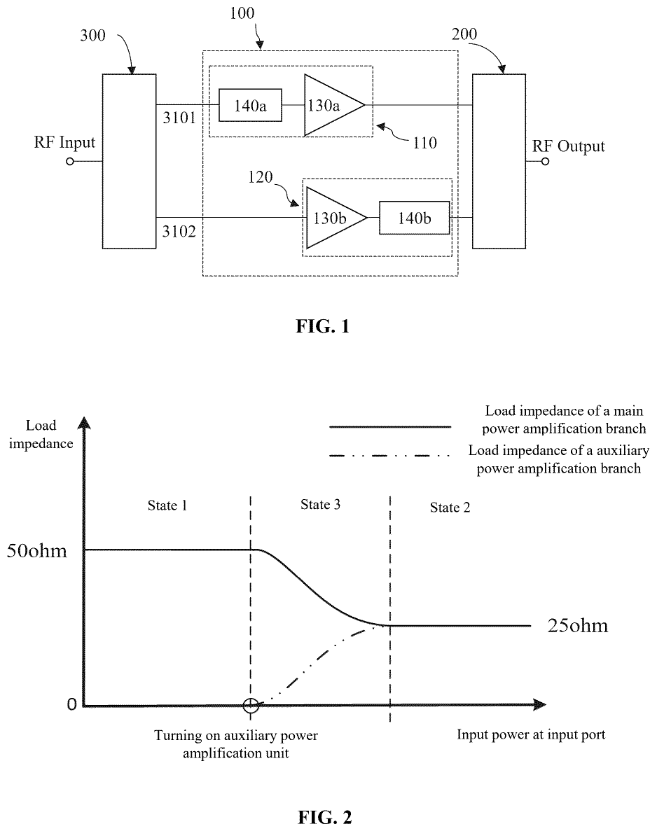

In some embodiments, when an output power of the power amplifier system is less than a first threshold, the at least one main power amplification branch is in the operating state, and the at least one auxiliary power amplification branch is in the off state. In conjunction with FIG. 1, when the output power of the power amplifier system is less than the first threshold, the main power amplification branch 110 is in the operating state, and the auxiliary power amplification branch 120 is in the off state. Referring to state 1 shown in FIG. 2, at this time, only the main power amplification unit 130a in the main power amplification branch 110 is turned on, the auxiliary power amplification unit 130b in the auxiliary power amplification branch 120 is in the off state, and the auxiliary power amplification branch 120 presents a low resistance state at a port of the in-phase synthesizer 200.

In some embodiments, when the output power of the power amplifier system is not less than the first threshold, the at least one auxiliary power amplification branch is in the operating state. When the at least one auxiliary power amplification branch is in the operating state, the load modulation is performed on the at least one main power amplification branch to reduce the load impedance of the at least one main power amplification branch, until a difference between the load impedance of the at least one main power amplification branch and the load impedance of the at least one auxiliary power amplification branch is less than a second threshold. Again in conjunction with FIG. 1, when the output power of the power amplifier system is not less than the first threshold, the auxiliary power amplification branch 120 is in the operating state. When the auxiliary power amplification branch 120 is in the operating state, the load modulation is performed on the main power amplification branch 110 to reduce the load impedance of the main power amplification branch 110, until a difference between the load impedance of the main power amplification branch 110 and the load impedance of the auxiliary power amplification branch 120 is less than the second threshold. Referring to state 2 and state 3 shown in FIG. 2, starting from state 3, both the main power amplification unit 130a and the auxiliary power amplification unit 130b are turned on, but at the beginning, the output power of the main power amplification unit 130a is different from the output power of the auxiliary power amplification unit 130b, and the output power of the auxiliary power amplification unit 130b creates a load modulation effect on the main power amplification unit 130a until the main power amplification unit 130a and the auxiliary power amplification unit 130b both maintain the same operating state (including, but not limited to, the main power amplification unit 130a and the auxiliary power amplification unit 130b both reaching a saturation state and outputting the same power), and the difference between the load impedance of the main power amplification branch 110 and the load impedance of the auxiliary power amplification branch 120 is less than the second threshold.

It should be noted here that in the embodiments of the present disclosure, the specific values of the first threshold and the second threshold are not limited, and may be set according to the actual product requirements without violating the inventive concept of the present disclosure. For example, the first threshold and/or the second threshold may be 0 or any number that is non-zero (e.g., 1, 0.1, 0.2, 0.5, 2.3, 1.7, etc.).

In some embodiments, an initial load impedance of the at least one main power amplification branch is ZC, a count of the at least one auxiliary power amplification branch is N, and when the load impedance of the at least one main power amplification branch is reduced to be equal to the load impedance of the at least one auxiliary power amplification branch, the load impedance of the at least one main power amplification branch becomes ZC/(N+1).

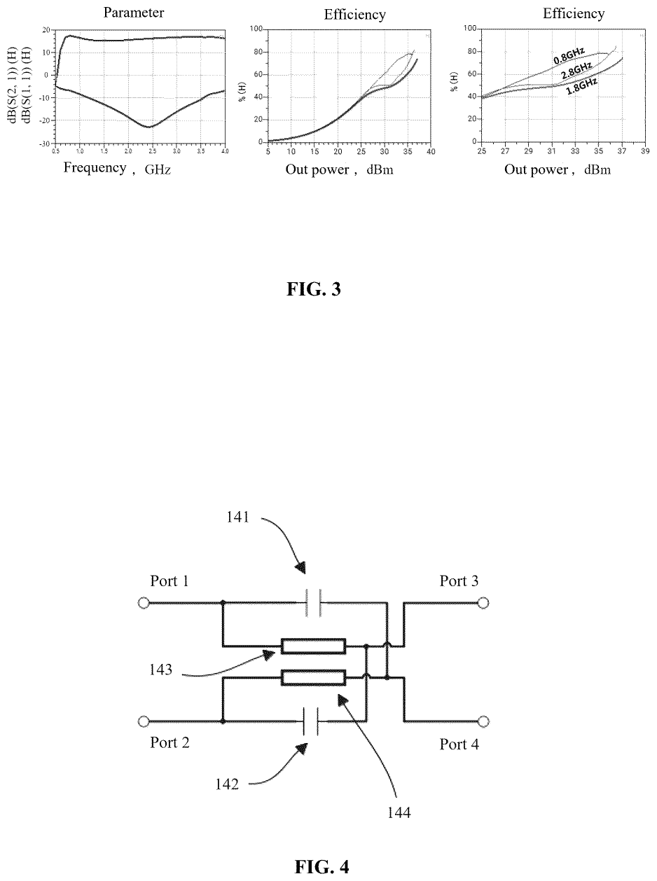

FIG. 2 is a schematic diagram illustrating impedance variation with an operating state of the power amplifier system based on in-phase power synthesis according to Embodiment 1 of the present disclosure. FIG. 3 is a schematic diagram illustrating simulation results of the power amplifier system based on in-phase power synthesis according to Embodiment 1 of the present disclosure. With further reference to FIG. 2, the main power amplification unit 130a of the power amplifier system is in the operating state, biased with an operating current to provide a small signal amplification gain. The auxiliary power amplification unit 130b is in the Class C state, with the operating current less than 1 mA, and may be considered to be in the off state. Typically, the output of the auxiliary power amplification unit 130b is presented as a high impedance, which may be converted to a low impedance at the port (e.g., the input port) of the in-phase synthesizer 200 via the second impedance conversion network 140b. As shown in state 1 in FIG. 2, at this time, the load impedance of the main power amplification unit 130a is close to 50 ohm. When the input power is relatively low (e.g., less than 0 dBm), the auxiliary power amplification unit 130b is still in the Class C state, and the architecture of the power amplifier system has an overall gain of 16 dB and a gain bandwidth covering 1 GHz to 3 GHz, as shown in the first subplot of FIG. 3. Continuing to increase the input power to reach the state 3 shown in FIG. 2, the efficiency of the output power reaches 40% when the output power reaches the first threshold (e.g., 25 dBm), as shown in the second subplot of FIG. 3. At this time, the auxiliary power amplification unit 130b also begins to output RF power to participate in power synthesis; the load impedance of the main power amplification unit 130a becomes less than 50 ohm, due to the load modulation effect of the auxiliary power amplification branch 120. Continuing to increase the input power to reach the state 2 shown in FIG. 2, when the output power of the main power amplification unit 130a is close to the output power of the auxiliary power amplification unit 130b, the load impedance of the main power amplification unit 130a is close to 25 ohm, and the load impedance of the auxiliary power amplification unit 130b is close to 25 ohm. At this time, the load impedance of the power amplifier system transitions from an initial 50 ohm to the combined impedance of two 25 ohm in parallel, representing a 4:1 impedance transformation (equivalent to 6 dB). In this embodiment, with a frequency in a range of 1 GHz˜3 GHz and power back-off from saturation of 6 dB, the output power efficiency maintains 45%˜70%.

As can be seen from the foregoing, when the initial load impedance of the main power amplification branch 110 is 50 ohm and a count N of the auxiliary power amplification branch is 1, and when the load impedance of the main power amplification branch 110 is reduced to be equal to the load impedance of the auxiliary power amplification branch 120, the load impedance of the main power amplification branch 110 becomes 25 ohm (ZC/(N+1)=50/(1+1)=25 ohm), which is the same as the experimental results.

It should be understood that the initial load impedance of the main power amplification branch 110 is set to an industry-standard impedance value (i.e., 50 ohm) so that under this impedance matching, a signal can be transmitted at maximum power in the circuit. This means that signal attenuation and reflection are minimized during signal transmission, thus ensuring signal quality and stability.

In some embodiments, the impedance conversion network in each of the power amplification branches includes a first capacitor, a second capacitor, a first coupling line, and a second coupling line. A first end of the first capacitor and a first end of the first coupling line are connected to a first input port of the impedance conversion network, and a first end of the second capacitor and a first end of the second coupling line are connected to a second input port of the impedance conversion network, respectively. A second end of the second capacitor and a second end of the first coupling line are connected to a first output port of the impedance conversion network, and a second end of the first capacitor and a second end of the second coupling line are connected to a second output port of the impedance conversion network, respectively.

FIG. 4 is a schematic diagram illustrating a circuit of an impedance conversion network according to Embodiment 1 of the present disclosure. In some specific embodiments, as shown in FIG. 4, the impedance conversion network (including the first impedance conversion network 140a and the second impedance conversion network 140b) may include a first capacitor 141, a second capacitor 142, a first coupling line 143, and a second coupling line 144. The first end of the first capacitor 141 and the first end of the first coupling line 143 are connected to the first input port (e.g., port 1) of the impedance conversion network, and the first end of the second capacitor 142 and the first end of the second coupling line 144 are connected to a second input port (e.g., port 2) of the impedance conversion network, respectively; and the second end of the second capacitor 142 and the second end of the first coupling line 143 are connected to a first output port (e.g., port 3) of the impedance conversion network, and the second end of the first capacitor 141 and the second end of the second coupling line 144 are connected to a second output port (e.g., port 4) of the impedance conversion network, respectively.

It should be noted that, in the embodiments of the present disclosure, the impedance conversion network mainly serves to perform the load modulation, converting the power amplification unit from a high-resistance state to a low-resistance state. Therefore, the specific realization of the impedance conversion network is not limited, and in addition to the above structure of the impedance conversion network, other forms of impedance conversion networks may also be used in the embodiments of the present disclosure

The in-phase synthesizer 200 may perform power synthesis on in-phase (or 180° inverted) signals. In some embodiments, the in-phase synthesizer includes a plurality of signal input ports, a signal output port, and M pairs of coupling lines connected between the plurality of signal input ports and the signal output port, M is equal to the count of power amplification branches. A positive input port and a negative input port of at least one pair of signal input ports in a plurality of signal input port are connected to a positive coupling line and a negative coupling line of different pairs of coupling lines, respectively. That is, the positive input port and the negative input port of the at least one pair of signal input ports are connected to the positive coupling line and the negative coupling line of two different pairs of coupling lines, for example, the positive input port is connected to a positive coupling line of a first pair of coupling lines, and the negative input port is connected to a negative coupling line of a second pair of coupling lines, the first pair of coupling lines and the second pair of coupling lines being two different pairs of coupling lines.

In some embodiments, the plurality of signal input ports of the in-phase synthesizer are not isolated from each other.

In some embodiments, an isolation module is disposed between at least two of the plurality of signal input ports of the in-phase synthesizer 200. In order to increase the isolation, isolation modules (not shown in the figure) may be disposed between the same-polarity ports of different signal input ports, for example, between the positive ports of different signal input ports, and/or between the negative ports of different signal input ports. The isolation module may include an isolation resistor, or include an isolation resistor and a capacitor that are in a parallel connection.

In some embodiments, the in-phase synthesizer 200 includes a plurality of signal input ports, a signal output port, a signal output port, and M pairs of coupling lines connected between the plurality of signal input ports and the signal output port; wherein a positive input port and a negative input port of each of the plurality of signal input ports are connected to a positive coupling line and a negative coupling line of a corresponding pair of coupling lines, respectively, and M is equal to the count of the plurality of power amplification branches. That is, the positive input port and the negative input port of one of the signal input ports are connected to the positive coupling line and the negative coupling line of a same pair of coupling lines, respectively. In some embodiments, the isolation module is disposed between at least two of the signal input ports of the in-phase synthesizer.

The following is an example of the in-phase synthesizer 200 provided by embodiments of the present disclosure with M=2.

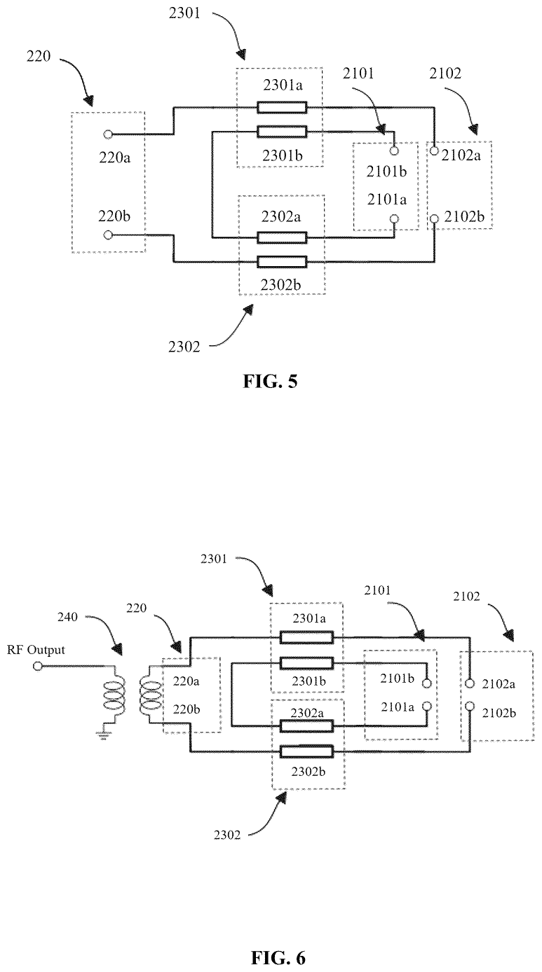

FIG. 5 is a schematic diagram illustrating a circuit of an in-phase synthesizer according to Embodiment 1 of the present disclosure, which illustrates a synthesizer using a differential structure.

Referring to FIG. 5, the in-phase synthesizer 200 may include two signal input ports 2101 and 2102, one signal output port 220, and two pairs of coupling lines 2301 and 2302. The two pairs of coupling lines 2301 and 2302 are connected between the two signal input ports 2101, 2102, and the signal output port 220.

As shown in FIG. 5, the signal input port 2101 includes a positive input port 2101a and a negative input port 2101b, and the signal input port 2102 includes a positive input port 2102a and a negative input port 2102b. The positive input port 2101a of the signal input port 2101 is connected to the positive coupling line 2302a of the second pair of coupling lines 2302, and the negative input port 2101b is connected to the negative coupling line 2301b of the first pair of coupling lines 2301. The negative coupling line 2301b of the first pair of coupling lines 2301 is connected to the positive coupling line 2302a of the second pair of coupling lines 2302, e.g., in series, etc. The positive input port 2102a of the signal input port 2102 is connected to the positive coupling line 2301a of the first pair of coupling lines 2301, and the negative input port 2102b is connected to the negative coupling line 2302b of the second pair of coupling lines 2302.

A positive output port 220a of the signal output port 220 is connected to the positive coupling line 2301a of the first pair of coupling lines 2301, and a negative output port 220b is connected to the negative coupling line 2302b of the second pair of coupling lines 2302.

FIG. 6 is another schematic diagram illustrating the circuit of the in-phase synthesizer according to Embodiment 1 of the present disclosure. Referring to FIG. 6, a difference from FIG. 5 is that the output port (RF Output) is a single-ended output port, i.e., the output signal of the output port (RF Output) is a single-ended output signal. In some embodiments, an output balun 240 may be connected between the output port (RF Output) and the signal output port 220 of the in-phase synthesizer 200. The output balun 240 serves as a converter from differential signals to single-ended signals, and may couple the signal output port 220 of the in-phase synthesizer 200 to the output port (RF Output), and convert the differential signals output by the in-phase synthesizer 200 to the single-ended signals. In some embodiments, the output baron 240 may be set according to actual requirements. For example, the output balun 240 may be a balun with an impedance ratio of 1:1.

In some embodiments, the power amplifier system may further include an in-phase power divider connected between the input port and the plurality of power amplification branches, the in-phase power divider is configured to perform power division on the input signal received from the input port to obtain a plurality of signals of the same phase before output. That is, the in-phase power divider includes a plurality of output ports. Each of the plurality of power amplification branches may be connected to one output port of the in-phase power divider to receive one signal of the same phase and to amplify the signal. That is, in this case, each of the plurality of power amplification branches is connected to one output port of the in-phase power divider to amplify the input signal of the same phase that is received from the output port.

With further reference to FIG. 1, in some specific embodiments, the power amplifier system further includes an in-phase power divider 300 connected between the input port (RF Input) and the plurality of power amplification branches 100, the in-phase power divider 300 is configured to perform power division on the input signal received from the input port (RF Input) to obtain a plurality of signals of the same phase before output.

The in-phase power divider 300 receives an input signal from the input port (RF Input) and distributes power to the input signal to output N differential signals (N≥2), for example, to output two or more signals of the same phase. Exemplarily, as shown in FIG. 1, the in-phase power divider 300 may include two output ports 3101 and 3102, respectively.

Each of the signals of the same phase output from the in-phase power divider 300 is amplified by one of the plurality of power amplification branches 100, and an amplified signal of the same phase is obtained. In FIG. 1, the plurality of power amplification branches 100 includes a main power amplification branch 110 and an auxiliary power amplification branch 120 for amplifying the signals of the same phase for each of the power amplification branches, the main power amplification branch 110 and the auxiliary power amplification branch 120 are configured to amplify signals of the same phase output from the output ports 3101 and 3102, respectively, to obtain two amplified signals of the same phase.

In some embodiments, if the initial input signal (the input signal at the input port (RF Input)) is a single-ended input signal and the in-phase power divider 300 is a power divider using a differential structure, an input balun (not shown in FIG. 1) may be connected between the single-ended signal input port and the differential signal input port (not shown in FIG. 1) of the in-phase power divider 300. The input balun (not shown in FIG. 1) serves as a converter from single-ended signal to differential signals, and may couple the single-ended signal input port (RF Input) to the differential signal input port of the in-phase power divider 300, such as the input balun 240. The input balun (not shown in FIG. 1) may be a balun with an impedance ratio of 1:1.

It should be noted that the circuit structures of the in-phase power divider 300 and the in-phase synthesizer 200 in the embodiment of the present disclosure are mutually reversible, and thus it needs to use only the plurality of signal input ports of the in-phase synthesizer 200 shown in FIG. 5 or FIG. 6 as the plurality of signal output ports of the in-phase power divider 300, and use the signal output ports of the in-phase synthesizer 200 as the signal input ports of the in-phase power divider 300, then the entire circuit structure of the in-phase synthesizer 200 may still be performed to the in-phase power divider 300

In the power amplifier system based on in-phase power synthesis, the circuit structures of the differential in-phase power divider and the differential in-phase synthesizer may be selected to be of different structures, for example, the in-phase synthesizer 200 adopts the differential power divider structure as illustrated in FIG. 5, and the in-phase power divider 300 adopts a reverse operating mode of the differential power divider structure as illustrated in FIG. 6 (i.e., the operating mode of synthesizer).

Of course, in the power amplifier system, the circuit structures of the in-phase power divider 300 and the in-phase synthesizer 200 may be selected to be essentially the same structure, for example, the in-phase power divider 300 adopts the reverse operating mode of the in-phase synthesizer structure illustrated in FIG. 5 or FIG. 6 (i.e., the operating mode of power divider), and the in-phase synthesizer 200 adopts the in-phase synthesizer structure illustrated in FIG. 5 or FIG. 6.

In some embodiments, each of the plurality of power amplification branches further includes at least one of an input impedance matching circuit located on a signal input side of the power amplification unit or an output impedance matching circuit located on a signal output side of the power amplification unit.

In order to achieve optimization of impedance matching in the plurality of power amplification branches 100, in a preferred embodiment, at least one of the power amplification branches may include an impedance matching circuit, wherein the impedance matching circuit is configured to achieve impedance matching of the power amplification units in the power amplification branches. The impedance matching may include at least one of the input impedance matching circuit located on the signal input side of the power amplification unit or the output impedance matching circuit located on the signal output side of the power amplification unit. Thus, the impedance matching circuit may thus include the input impedance matching circuit, the output impedance matching circuit, or a combination thereof.

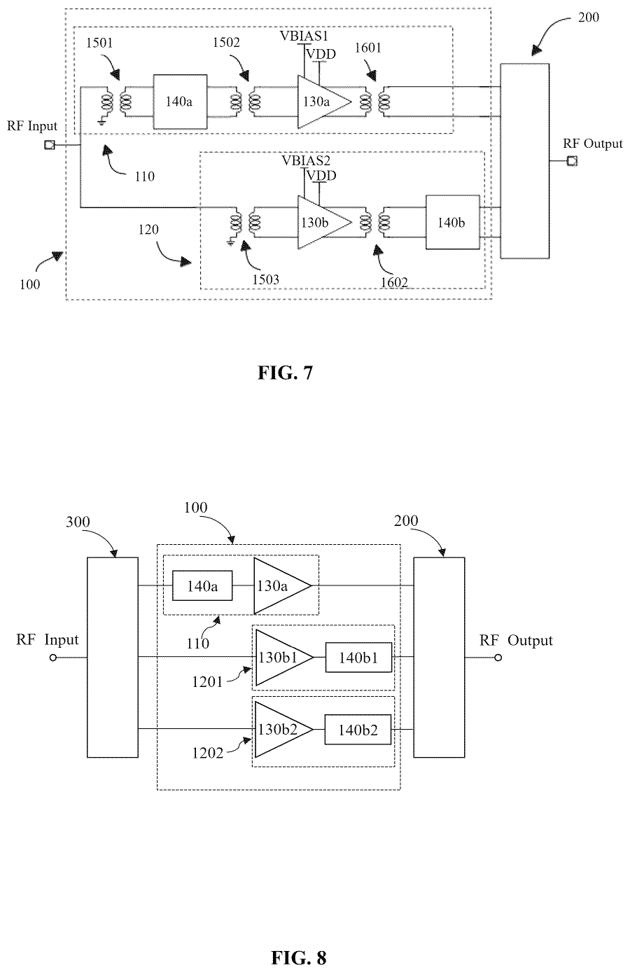

FIG. 7 is another architecture diagram illustrating the power amplifier system based on in-phase power synthesis according to Embodiment 1 of the present disclosure. Referring to FIG. 7, an example is particularly illustrated where each of the power amplification branches 100 includes an impedance matching circuit, and the impedance matching circuit includes an input impedance matching circuit and an output impedance matching circuit. For example, the main power amplification branch 110 includes an input impedance matching circuit 1501, a first impedance conversion network 140a, an input impedance matching circuit 1502, the main power amplification unit 130a, and an output impedance matching circuit 1601 disposed between the in-phase power divider 300 and the in-phase power synthesizer 200 in sequence, the input impedance matching circuits 1501, 1502, and the output impedance matching circuit 1601, are configured to match the input impedance and the output impedance of the main power amplification unit 130a, respectively. The auxiliary power amplification branch 120 includes an input impedance matching circuit 1503, an auxiliary power amplification unit 130b, an output impedance matching circuit 1602, and a second impedance conversion network 140b disposed between the in-phase power divider 300 and the in-phase power synthesizer 200 in sequence, wherein the input impedance matching circuit 1503 and the output impedance matching circuit 1602 are configured to match the input impedance and the output impedance of the auxiliary power amplification unit 130b, respectively.

### Embodiment 2

FIG. 8 is an architectural diagram illustrating a power amplifier system based on in-phase power synthesis according to Embodiment 2 of the present disclosure. As shown in FIG. 8, the power amplifier system based on in-phase power synthesis may include: the input port (RF Input), the output port (RF Output), the plurality of power amplification branches 100, and the in-phase synthesizer 200. The plurality of power amplification branches 100 and the in-phase synthesizer 200 are connected between the input port (RF Input) and the output port (RF Output) in sequence. Each of the plurality of power amplification branches 100 is connected to the input port (RF Input), and may receive an input signal from the input port (RF Input), and the input signals received by each of the power amplification branches have the same phase. The plurality of power amplification branches 100 are configured to amplify an input signal of the same phase received from each input port (RF Input) to obtain the amplified signal. The in-phase synthesizer 200 is connected between the plurality of power amplification branches 100 and the output port (RF Output), and is configured to perform power synthesis on the amplified signal at the same phase output from each of the plurality of power amplification branches to obtain a synthesized output signal, and transmit the synthesized output signal to the output port (RF Output) for output.

A difference with Embodiment 1 is that in Embodiment 2, the plurality of power amplification branches 100 as shown in FIG. 8 includes the main power amplification branch 110, and two auxiliary power amplification branches 1201, 1202. That is, the plurality of power amplification branches 100 adopts a three-channel power amplifier, and by compensating the phases between different branches, the signals output from the plurality of power amplification branches may be synthesized in the same phase.

With further reference to FIG. 8, the main power amplification branch 110 may include the main power amplification unit 130a and the first impedance conversion network 140a; the auxiliary power amplification branch 1201 may include the auxiliary power amplification unit 130b1 and the second impedance conversion network 140b1; and the auxiliary power amplification branch 1202 may include an auxiliary power amplification unit 130b2 and a second impedance conversion network 140b2. The main power amplification branch 110 in Embodiment 2 has the same structure as the main power amplification branch 110 in Embodiment 1, and the two auxiliary power amplification branches 1201, 1202 are all of the same structure as the auxiliary power amplification branch 120 in Embodiment 1, and the relevant contents may be referred to as shown in the foregoing, and will not be repeated herein.

In some specific embodiments, the power amplification unit used in the main power amplification branch 110 is different from the power amplification unit used in the auxiliary power amplification branches 1201, 1202, and the two auxiliary power amplification branches 1201 and 1202 adopt power amplification units of the same type. That is, the two auxiliary power amplification branches 1201, 1202 adopt power amplification units of the same type (e.g., a first type), and the main power amplification branch 110 adopts a power amplification unit of a type (e.g., a second type) different from that of the two auxiliary power amplification branches 1201, 1202.

In some specific embodiments, the impedance conversion network of the main power amplification branch 110, the impedance conversion network of the auxiliary power amplification branch 1201, and the impedance conversion network of the auxiliary power amplification branch 1202, may be the same or different, and are not specifically limited here, but can be set according to actual product requirements when implemented. For example, the main power amplification branch 110, the auxiliary power amplification branch 1201, and the auxiliary power amplification branch 1202, may adopt impedance conversion networks of the same phase offset, so as to ensure that the phases of the amplified signals output from the main power amplification branch 110 and the auxiliary power amplification branches 1201, 1202 are the same during power synthesis in the in-phase synthesizer 200.

In some specific embodiments, the main power amplification branch 110 and the two auxiliary power amplification branches 1201, 1202 are configured to amplify an input signal of a same phase received from the input port (RF Input) (i.e., the plurality of power amplification branches 100 shown in FIG. 8 may amplify three input signals). In some embodiments, when the auxiliary power amplification branches 1201 and 1202 are in the operating state, a load modulation is performed on the main power amplification branch by at least one of the auxiliary power amplification branches 1201 and 1202 to reduce a load impedance of the main power amplification branch 110.

In some specific embodiments, when the output power of the power amplifier system is less than the first threshold, the main power amplification branch 110 is in the operating state, and the auxiliary power amplification branches 1201, 1202 are in the off state. At this time, only the main power amplification unit 130a in the main power amplification branch 110 is turned on, and the auxiliary power amplification units 130b1 and 130b2 in the two auxiliary power amplification branches are in the off state. The auxiliary power amplification units 130b1 and 130b2 present a low resistance state at the input port of the in-phase synthesizer 200. When the output power of the power amplifier system is not less than the first threshold, at least one of the auxiliary power amplification branches 1201 and 1202 is in the operating state (e.g., both the auxiliary power amplification branches 1201 and 1202 are in the operating state). When the auxiliary power amplification branches 1201 and/or 1202 are in the operating state, the load modulation is performed on the main power amplification branch 110 by the auxiliary power amplification branches 1201 and/or 1202 to reduce the load impedance of the main power amplification branch 110 until the difference between the load impedance of the main power amplification branch 110 and the load impedance of the auxiliary power amplification branch 1201/1202 is less than the second threshold. For example, the difference between the load impedance of the main power amplification branch 110 and the load impedance of each of the two auxiliary power amplification branches 1201, 1202 is less than the second threshold. The main power amplification unit 130a and the auxiliary power amplification units 130b1, 130b2 are turned on, but at the beginning, the output power of the main power amplification unit 130a is different the output power of the auxiliary power amplification units 130b1, 130b2, and the output power of the auxiliary power amplification units 130b1 and 130b2 forms a load modulation effect on the main power amplification unit 130a, until the main power amplification unit 130a and the two auxiliary power amplification units 130b1, 130b2 are maintained in the same operating state (including, but not limited to, the main power amplification unit 130a, the auxiliary power amplification unit 130b1, and the auxiliary power amplification unit 130b2 all reaching the saturation state and outputting the same power), and the difference of the load impedance of the main power amplification branch 110 and the load impedance of the auxiliary power amplification branch 1201 and the difference of the load impedance of the main power amplification branch 110 and the load impedance of the auxiliary power amplification branch 1202 are all less than the second threshold.

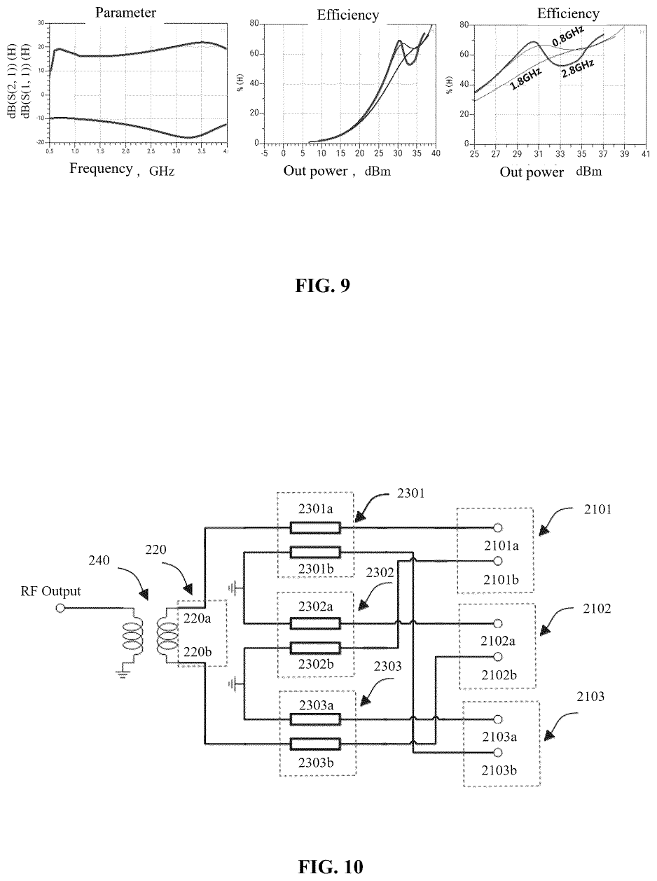

FIG. 9 is a schematic diagram illustrating simulation results of the power amplifier system based on in-phase power synthesis according to Embodiment 2 of the present disclosure. The main power amplification unit 130a in the power amplifier system architecture is in the operating state, biased with the operating current to provide small signal amplification gain. The auxiliary power amplification unit 130b1 and the auxiliary power amplification unit 130b2 are both in the class C state, with the operating current less than 1 mA, which may be considered to be in the off state. At this time, the outputs of the auxiliary power amplification unit 130b1 and the auxiliary power amplification unit 130b2 are presented as high impedance, which may be converted into a low impedance via the second impedance conversion network 140b1 and the second impedance conversion network 140b2 at the port of the in-phase synthesizer, respectively. At this point, the load impedance of the main power amplification unit 130a is close to 50 ohm. When the input power is relatively low (e.g., less than 0 dBm), the auxiliary power amplification unit 130b1 and the auxiliary power amplification unit 130b2 are still in the Class C state, and the architecture of the power amplifier system has an overall gain of 16 dB and a gain bandwidth covering 1 GHz to 3 GHz, as shown in the first subplot of FIG. 9. Continuing to increase the input power, the efficiency of the output power at all frequency points in the band reaches 35% when the output power reaches the first threshold (e.g., 25 dBm), as shown in the second subplot of FIG. 9. At this time, the auxiliary power amplification units 130b1 and 130b2 also begin to output RF power to participate in power synthesis; the load impedance of the main power amplification unit 130a becomes less than 50 ohm, due to the load modulation effect of the auxiliary power amplification branches 1201 and 1202. Continuing to increase the input power, when the output power of the main power amplification unit 130a is close to the output power of the auxiliary power amplification units 130b1 and 130b2, the load impedance of the main power amplification unit 130a is close to 17 ohm, and the load impedance of the auxiliary power amplification units 130b1 and 130b2 are both close to 27 ohm. At this time, the load impedance of the power amplifier system transitions from an initial 50 ohm to the combined impedance of three 17 ohm in parallel, representing a 9:1 impedance transformation (equivalent to 9 dB). In this embodiment, with a frequency in a range of 1 GHz˜3 GHz and power back-off from saturation of 9 dB, the output power efficiency maintains 45%˜70%.

As can be seen from the foregoing, when the initial load impedance of the main power amplification branch 110 is 50 ohm and the count N of the auxiliary power amplification branch is 2, and when the load impedance of the main power amplification branch 110 is reduced to be equal to the load impedance of the auxiliary power amplification branch, the load impedance of the main power amplification branch 110 becomes 17 ohm (ZC/(N+1)=50/(2+1)=17 ohm), which is the same as the experimental results.

FIG. 10 is a schematic diagram illustrating a circuit of an in-phase synthesizer according to Embodiment 2 of the present disclosure, and with reference to FIG. 10, the in-phase synthesizer 200 in the embodiment of the present disclosure also has a different structure from that of Embodiment 1. With further reference to FIG. 10, the in-phase synthesizer 200 in embodiment 2 may include three signal input ports 2101, 2102, 2103, one signal output port 220, and three pairs of coupling lines 2301, 2302, and 2303. The three pairs of coupling lines 2301, 2302, and 2303 are connected between the three signal input ports 2101, 2102, 2103 and the signal output port 220.

The signal input port 2101 includes a positive input port 2101a and a negative input port 2101b, the signal input port 2102 includes a positive input port 2102a and a negative input port 2102b, the signal input port 2103 includes a positive input port 2103a and a negative input port 2103b. As shown in FIG. 10, the positive input port 2101a of the signal input port 2101 is connected to the positive coupling line 2301a of the first pair of coupling lines, and the negative input port 2101b is connected to the negative coupling line 2302b of the second pair of coupling lines 2302. The positive input port 2102a of the signal input port 2102 is connected to the positive coupling line 2302a of the second pair of coupling lines 2302, and the negative input port 2102b is connected to a negative coupling line 2303b of the third pair of coupling lines 2303. The positive input port 2103a of the signal input port 2103 is connected to a positive coupling line 2303a of the third pair of coupling lines 2303, and the negative input port 2103b is connected to the negative coupling line 2301b of the first pair of coupling lines 2301. The positive coupling line 2301a of the first pair of coupling lines 2301 is connected to the negative coupling line 2303b of the third pair of coupling lines 2303, and the negative coupling line 2301b of the first pair of coupling lines 2301 is connected to positive coupling line 2302a of the second pair of coupling lines 2302, the negative coupling line 2302b of the second pair of coupling lines 2302 is connected to the positive coupling line 2303a of the third pair of coupling lines 2303, and the connection may be, for example, in series or the like.

The positive output port 220a of the signal output port 220 is connected to the positive coupling line 2301a of the first pair of coupling lines 2301, and the negative output port 220b is connected to the negative coupling line 2302b of the third pair of coupling lines 2303.

In some implementations, as shown in FIG. 8, the power amplifier system further includes the in-phase power divider 300 connected between the input port (RF Input) and the plurality of power amplification branches 100, the in-phase power divider 300 is configured to perform power division on the input signal received from the input port (RF Input) to obtain a plurality of signals of the same phase before output. In some embodiments, the in-phase power divider 300 in Embodiment 2 may adopt a reverse operating mode (i.e., the operating mode of power divider) of the in-phase synthesizer structure shown in FIG. 10. In some embodiments, the in-phase power divider 300 in Embodiment 2 may adopt a reverse operating mode of synthesizer such as that illustrated in FIG. 5 or FIG. 6, or other structural forms of power dividers.

### Embodiment 3

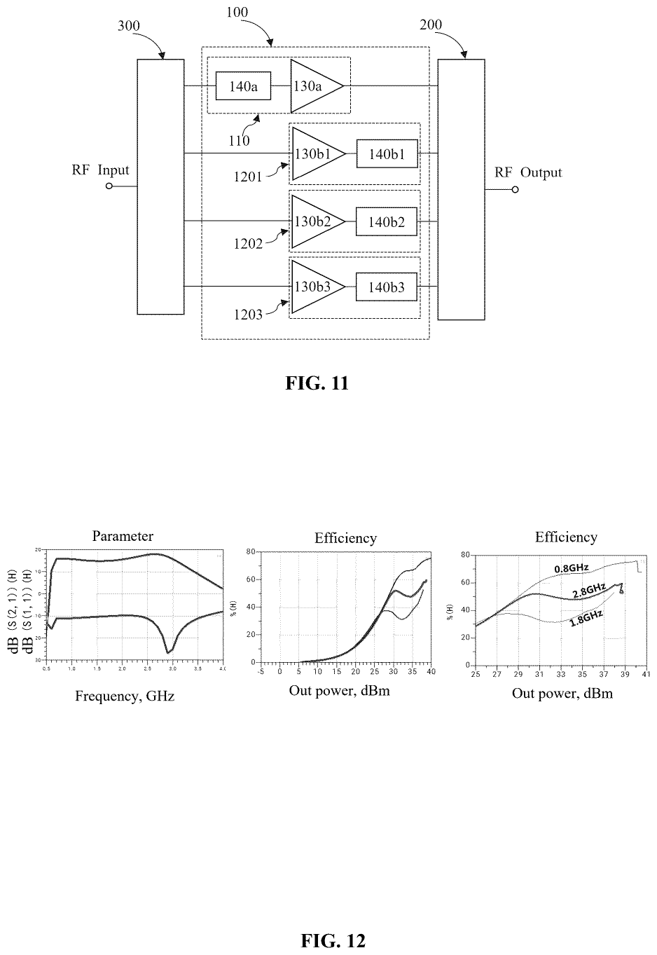

FIG. 11 is an architectural diagram illustrating a power amplifier system based on in-phase power synthesis according to Embodiment 3 of the present disclosure. As shown in FIG. 11, the power amplifier system based on in-phase power synthesis may include: the input port (RF Input), the output port (RF Output), the plurality of power amplification branches 100, and the in-phase synthesizer 200. The plurality of power amplification branches 100 and the in-phase synthesizer 200 are connected between the input port (RF Input) and the output port (RF Output) in sequence. Each of the plurality of power amplification branches 100 is connected to the input port (RF Input), and may receive an input signal from the input port (RF Input), and the input signal received by each of the power amplification branches has the same phase. The plurality of power amplification branches 100 are configured to amplify an input signal of a same phase received from each input port (RF Input) to obtain an amplified signal. The in-phase synthesizer 200 is connected between the plurality of power amplification branches 100 and the output port (RF Output), and is configured to perform power synthesis on the amplified signal at the same phase output from each of the plurality of power amplification branches to obtain a synthesized output signal, and transmit the synthesized output signal to the output port (RF Output) for output.

A difference with Embodiment 1 and Embodiment 2 is that, in Embodiment 3, the plurality of power amplification branches 100 as shown in FIG. 8 includes the main power amplification branch 110, and three auxiliary power amplification branches 1201, 1202 and 1203. That is, the plurality of power amplification branches 100 adopts a four-channel power amplifier, and by performing phase compensation between different branches, power synthesis of output signals from the plurality of power amplification branches at the same phase may be achieved.

Further referring to FIG. 11, the main power amplification branch 110 in Embodiment 3 has the same structure as the main power amplification branch 110 in Embodiment 1, and the three auxiliary power amplification branches 1201, 1202, 1203 have the same structure as the auxiliary power amplification branch 120 in Embodiment 1. The relevant contents may be referred to as shown in the foregoing, and will not be repeated herein.

In some specific embodiments, the power amplification unit used in the main power amplification branch 110 is different from the power amplification units used in the auxiliary power amplification branches 1201, 1202, 1203, the auxiliary power amplification branches 1201, 1202, and 1203 use the same type of power amplification units. That is, the three auxiliary power amplification branches 1201, 1202, and 1203 use the same type of power amplification units, and the type of power amplification unit of the main power amplification branch 110 is different from the type of power amplification unit used by each of the auxiliary power amplification branches.

In some specific embodiments, structures of the impedance conversion network of the main power amplification branch 110, the impedance conversion network of the auxiliary power amplification branch 1201, the impedance conversion network of the auxiliary power amplification branch 1202, and the impedance conversion network of the auxiliary power amplification branch 1203 may be the same or different, here is not a specific limit, the specific implementation can be set according to the actual product requirements. For example, the main power amplification branch 110, the auxiliary power amplification branch 1201, the auxiliary power amplification branch 1202, and the auxiliary power amplification branch 1203 may adopt impedance conversion networks with the same phase offset, so as to ensure that the phases of the amplified signals output from the main power amplification branch 110 and the auxiliary power amplification branches 1201, 1202, 1203 are the same during power synthesis in the in-phase synthesizer 200.

In some specific embodiments, both the main power amplification branch 110 and the auxiliary power amplification branches 1201, 1202, 1203 are configured to amplify an input signal of a same phase received from the input port (RF Input). In some embodiments, when the auxiliary power amplification branches 1201, 1202, and 1203 are in the operating state, a load modulation is performed on the main power amplification branch by at least one of the auxiliary power amplification branches 1201, 1202, and 1203 to reduce a load impedance of the main power amplification branch 110.

In some specific embodiments, when the output power of the power amplifier system is less than the first threshold, the main power amplification branch 110 is in the operating state, the auxiliary power amplification branches 1201, 1202, 1203 are in the off state. At this time, only the main power amplification unit 130a is turned on, the auxiliary power amplification units 130b1, 130b2, 130b3 are in the off state, and the auxiliary power amplification units 130b1, 130b2, 130b3 present the low resistance state at the port of the in-phase synthesizer 200. When the output power of the power amplifier system is not less than the first threshold, at least one of the auxiliary power amplification branches 1201, 1202 and 1203 is in the operating state (e.g., all of the auxiliary power amplification branches 1201, 1202 and 1203 are in the operating state). When at least one of the auxiliary power amplification branches 1201, 1202, 1203 is in the operating state, the load modulation is performed on the main power amplification branch 110, until the difference between the load impedance of the main power amplification branch 110 and the load impedance of at least one of the auxiliary power amplification branches 1201, 1202 or 1203 is less than the second threshold. For example, the difference between the load impedance of the main power amplification branch 110 and the load impedance of each of the three auxiliary power amplification branches is less than the second threshold. The main power amplification unit 130a and the auxiliary power amplification units 130b1, 130b2, 130b3 are turned on, but at the beginning, the output power of the main power amplification unit 130a is different from the output power of the auxiliary power amplification units 130b1, 130b2 and 130b3, and the output power of the auxiliary power amplification units 130b1, 130b2 and 130b3 forms a load modulation effect on the main power amplification unit 130a until the main power amplification unit 130a and the auxiliary power amplification units 130b1, 130b2 and 130b3 maintain the same operating state (including, but not limited to, the main power amplification unit 130a and the auxiliary power amplification units 130b1, 130b2 and 130b3 reaching the saturation state and outputting the same power), and the difference between the load impedance of the main power amplification branch 110 and the load impedance of the auxiliary power amplification branches 1201, 1202 and 1203 is less than the second threshold.

The main power amplification unit 130a of the power amplifier system architecture is in the operating state, biased with an operating current to provide a small signal amplification gain. The auxiliary power amplification unit 130b1, the auxiliary power amplification unit 130b2 and the auxiliary power amplification unit 130b3 are all in the class C state, with the operating current less than 1 mA, and may be considered to be in the off state. At this time, the outputs of the auxiliary power amplification unit 130b1, the auxiliary power amplification unit 130b2 and the auxiliary power amplification unit 130b3 are presented as high impedance, which may be converted into a low impedance via the second impedance conversion network 140b1, the second impedance conversion network 140b2, and the second impedance conversion network 140b3 at the port of the in-phase synthesizer 200, respectively. At this time, the load impedance of the main power amplification unit 130a is close to 50 ohm. FIG. 12 is a schematic diagram illustrating simulation results of the power amplifier system based on in-phase power synthesis according to Embodiment 3 of the present disclosure. When the input power is relatively low (e.g., less than 0 dBm), the auxiliary power amplification unit 130b1, the auxiliary power amplification unit 130b2 and the auxiliary power amplification unit 130b3 are still in the Class C state, and the architecture of the power amplifier system has an overall gain of 16 dB and a gain bandwidth covering 1 GHz to 3 GHz as shown in the first subplot of FIG. 12. Continuing to increase the input power, the efficiency of the output power reaches 35% at all frequency points in the band when the output power reaches the first threshold (e.g., 25 dBm), as shown in the second subplot of FIG. 12. At this time, the auxiliary power amplification unit 130b1, the auxiliary power amplification unit 130b2 and the auxiliary power amplification unit 130b3 also begin to output RF power to participate in power synthesis; the load impedance of the main power amplification unit 130a becomes less than 50 ohm, due to the load modulation effect of the auxiliary power amplification branches 1201, 1202 and 1203. Continuing to increase the input power, when the output power of the main power amplification unit 130a and the three auxiliary power amplification units 130b1, 130b2 and 130b3 are close to each other (i.e., the output power of the main power amplification unit 130a is close to the output power of each of the auxiliary power amplification units), the load impedance of the main power amplification unit 130a is close to 12.5 ohm, and the load impedance of the auxiliary power amplification unit 130b1, the auxiliary power amplification unit 130b2, the auxiliary power amplification unit 130b2 are all close to 12.5 ohm. At this time, the load impedance of the power amplifier system transitions from an initial 50 ohm to the combined impedance of four 12.5 ohm in parallel, representing a 16:1 impedance transformation (equivalent to 12 dB). In this embodiment, with a frequency in a range of 1 GHz˜3 GHz and power back-off from saturation of 12 dB, the output power efficiency maintains 35%˜70%. In addition, the efficiency of each power point at the 3 GHz frequency point in FIG. 12 is lower than the other two curves due to the parasitic capacitance of the amplifier tube core causing the output impedance of the amplifier to deviate from a high impedance state at 3 GHz.

As can be seen from the foregoing, when the initial load impedance of the main power amplification branch 110 is 50 ohm and the count N of the auxiliary power amplification branch is 3, when the load impedance of the main power amplification branch 110 is reduced to be equal to the load impedance of the auxiliary power amplification branches 1201, 1202 and 1203, the load impedance of the main power amplification branch 110 becomes 12.5 ohm (ZC/(N+1)=50/(3+1)=12.5 ohm), which is the same as the experimental results.

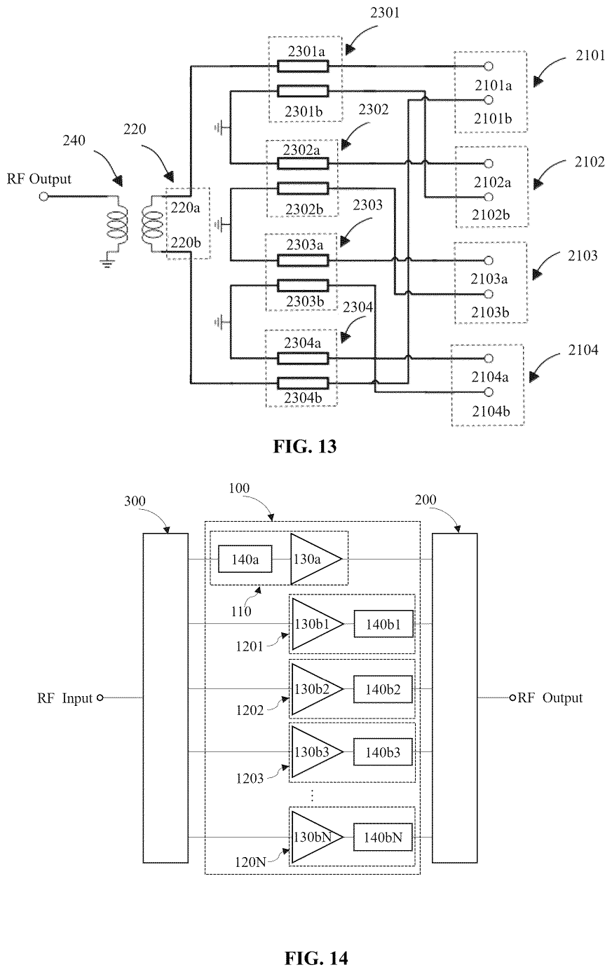

FIG. 13 is a schematic diagram illustrating a circuit of an in-phase synthesizer according to Embodiment 3 of the present disclosure. In addition to this, the structure of the in-phase synthesizer 200 in the Embodiment 3 is also different from that of the Embodiment 1, as shown with reference to FIG. 13. Further referring to FIG. 13, the in-phase synthesizer 200 in embodiment three includes four signal input ports 2101, 2102, 2103, 2104, one signal output port 220, and four pairs of coupling lines 2301, 2302, 2303, 2304. The four pairs of coupling lines 2301, 2302, 2303, and 2304 are connected to the four signal input ports 2101, 2102, 2103, 2104 and the signal output port 220.

The signal input port 2101 includes a positive input port 2101a and a negative input port 2101b, the signal input port 2102 includes a positive input port 2102a and a negative input port 2102b, the signal input port 2103 includes a positive input port 2103a and a negative input port 2103b, and the signal input port 2104 includes a positive input port 2104a and a negative input port 2104b.

As shown in FIG. 13, the positive input port 2101a of the signal input port 2101 is connected to the positive coupling line 2301a of the first pair of coupling lines 2301, and the negative input port 2101b is connected to the negative coupling line 2304b of the fourth pair of coupling lines 2304. The positive input port 2102a of the signal input port 2102 is connected to the positive coupling line 2302a of the second pair of coupling lines 2302, and the negative input port 2102b is connected to the negative coupling line 2301b of the first pair of coupling lines 2301. The positive input port 2103a of the signal input port 2103 is connected to the positive coupling line 2303a of the third pair of coupling lines 2303, and the negative input port 2103b is connected to the negative coupling line 2302 of the second pair of coupling lines 2302. The positive input port 2104a of the signal input port 2104 is connected to the positive coupling line 2304a of the fourth pair of coupling lines 2304, and the negative input port 2104b is connected to the negative coupling line 2303 of the third pair of coupling lines 2303. The positive coupling line 2301a of the first pair of coupling lines 2301 is connected to the negative coupling line 2304b of the fourth pair of coupling lines 2304, and the negative coupling line 2301b of the first pair of coupling lines 2301 is connected to the positive coupling line 2302a of the second pair of coupling lines 2302, the negative coupling line 2302b of the second pair of coupling lines 2302 is connected to the positive coupling line 2303a of the third pair of coupling lines 2303, and the negative coupling line 2303b of third pair of coupling lines 2303 is connected to the positive coupling line 2304a of the fourth pair of coupling lines 2304, and the connection may be, for example, in series or the like.

The positive output port 220a of the signal output port 220 is connected to the positive coupling line 2301a of the first pair of coupling lines 2301, and the negative output port 220b is connected to the negative coupling line 2304b of the fourth pair of coupling lines 2304.

In some embodiments, as shown in FIG. 11, the power amplifier system further includes the in-phase power divider 300 connected between the input port (RF Input) and the plurality of power amplification branches 100, the in-phase power divider 300 is configured to perform power division on the input signal received from the input port (RF Input) to obtain a plurality of signals of the same phase before output. In some embodiments, the in-phase power divider 300 in Embodiment 3 may adopt a reverse operating mode of the in-phase synthesizer structure shown in FIG. 13. In some embodiments, the in-phase power divider 300 in Embodiment 3 may adopt a reverse operating mode of the in-phase synthesizer structure such as that illustrated in FIG. 5, or FIG. 6, or FIG. 10, or other structural forms of the power divider.

### Embodiment 4

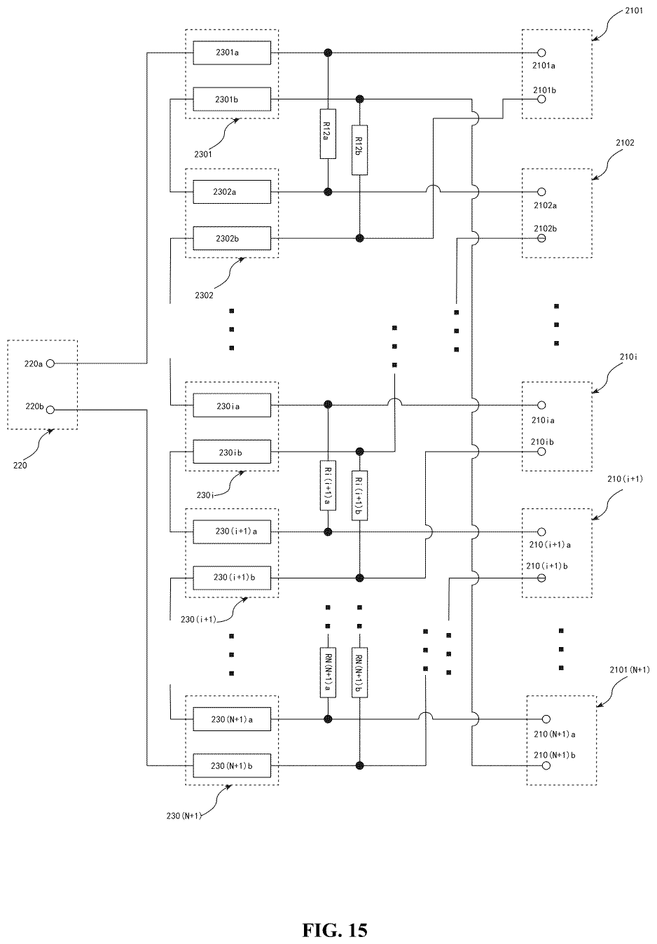

FIG. 14 is an architectural diagram illustrating a power amplifier system based on in-phase power synthesis according to Embodiment 4 of the present disclosure. As shown in FIG. 14, the power amplifier system based on in-phase power synthesis may include: the input port (RF Input), the output port (RF Output), the plurality of power amplification branches 100, and the in-phase synthesizer 200. The plurality of power amplification branches 100 and the in-phase synthesizer 200 are connected between the input port (RF Input) and the output port (RF Output) in sequence. Each of the plurality of power amplification branches 100 is connected to the input port (RF Input), and may receive an input signal from the input port (RF Input), and the input signals received by each of the power amplification branches have the same phase. The plurality of power amplification branches 100 are configured to amplify an input signal of a same phase received from each input port (RF Input) to obtain the amplified signal. The in-phase synthesizer 200 is connected between the plurality of power amplification branches 100 and the output port (RF Output), and is configured to perform power synthesis on the amplified signal at the same phase output from each of the plurality of power amplification branches to obtain a synthesized output signal, and transmit the synthesized output signal to the output port (RF Output) for output.

A difference with Embodiment 1 is that, in Embodiment 4 the plurality of main power amplification branches 100 includes a main power amplification branch 110 and N auxiliary power amplification branches 1201-120N, i.e., the plurality of power amplification branches 100 adopts a (N+1)-channel power amplifier, and by performing phase compensation between different branches, power synthesis of output signals from the plurality of power amplification branches at the same phase may be achieved.

With further reference to FIG. 14, the main power amplification branch 110 in Embodiment 4 has the same structure as the main power amplification branch 110 in Embodiment 1, and the structure of the N auxiliary power amplification branches 1201-120N is the same as that of the auxiliary power amplification branch 120 in Embodiment 1, and the relevant contents may be referred to as shown in the foregoing, and will not be repeated herein.

In some specific embodiments, the power amplification unit used in the main power amplification branch 110 is different from the power amplification units employed in the auxiliary power amplification branches 1201-120N, and the power amplification units used in the auxiliary power amplification branches 1201-120N are the same. That is, the power amplification unit used in the main power amplification branch 110 is different from the power amplification unit used in each of the N auxiliary power amplification branches, but the power amplification units used in the N auxiliary power amplification branches are the same.

In some specific embodiments, the impedance conversion network of the main power amplification branch 110 and the impedance conversion networks of the auxiliary power amplification branches 1201-120N may be the same or different, and are not specifically limited here, but can be set according to actual product requirements when implemented. For example, the main power amplification branch 110 and the auxiliary power amplification branches 1201-120N may adopt impedance conversion networks with the same phase offset, so as to ensure that the phases of the amplified signals output from the main power amplification branch 110 and the auxiliary power amplification branches 1201-120N are the same during power synthesis in the in-phase synthesizer 200.

In some specific embodiments, the main power amplification branch 110 and the auxiliary power amplification branches 1201-120N are configured to amplify an input signal of a same phase received from the input port (RF Input), and when the auxiliary power amplification branches 1201-120N are in the operating state, a load modulation is performed on the main power amplification branch 110 to reduce a load impedance of the at least one main power amplification branch 110.

In some specific embodiments, when the output power of the power amplifier system is less than the first threshold, the main power amplification branch 110 is in the operating state, and the auxiliary power amplification branches 1201-120N are in the off state. At this time, only the main power amplification unit 130a in the main power amplification branch 110 is turned on, and the auxiliary power amplification units 130b1-130bN in the N auxiliary power amplification branches are in the off state. The auxiliary power amplification units 130b1-130bN present a low resistance state at the input port of the in-phase synthesizer 200. When the output power of the power amplifier system is not less than the first threshold, the at least one of the N auxiliary power amplification branches 1201-120N is in the operating state (e.g., all of the N auxiliary power amplification branches 1201-120N are in the operating state). When the at least one of the N auxiliary power amplification branches 1201-120N is in the operating state, the load modulation is performed on the main power amplification branch 110 to reduce the load impedance of the main power amplification branch 110, until a difference between the load impedance of the main power amplification branch 110 and the load impedance of at least one of the N auxiliary power amplification branches 1201-120N is less than the second threshold. For example, the difference between the load impedance of the main power amplification branch 110 and the load impedance of each of the N auxiliary power amplification branches is less than the second threshold. The main power amplification unit 130a and the auxiliary power amplification units 130b1-130bN are turned on, but at the beginning, the output power of the main power amplification unit 130a is different from that of the auxiliary power amplification units 130b1-130bN, and the output power of the auxiliary power amplification units 130b1-130bN forms a load modulation effect on the main power amplification unit 130a until the main power amplification unit 130a and the auxiliary power amplification units 130b1-130bN maintain the same operating state (including, but not limited to, the main power amplification unit 130a and the auxiliary power amplification units 130b1-130bN reaching the saturation state and outputting the same power), and the difference between the load impedance of the main power amplification branch 110 and the load impedance of each of the auxiliary power amplification branches 1201-120N is less than the second threshold.

The main power amplification unit 130a in the power amplifier system architecture is in the operating state, biased with the operating current to provide small signal amplification gain. The auxiliary power amplification units 130b1-130bN are all in the class C state, with the operating current less than 1 mA, and may be considered to be in the off state, at this time, the outputs of the auxiliary power amplification units 130b1-130bN are presented as high impedance. The auxiliary power amplification units 130b1-130bN may be converted into a low impedance via the second impedance conversion networks 140b1-140bN at the input port of the in-phase synthesizer, respectively. At this point, the load impedance of the main power amplification unit 130a is close to 50 ohm. When the input power is relatively low (e.g., less than 0 dBm), the auxiliary power amplification units 130b1-130bN are still in the Class C state. Continuing to increase the input power, at this time, the auxiliary power amplification units 130b1-130bN also begin to output RF power to participate in power synthesis; the load impedance of the main power amplification unit 130a becomes less than 50 ohm, due to the load modulation effect of the auxiliary power amplification branches 1201-120N. Continuing to increase the input power, when the output power of the main power amplification unit 130a and the N auxiliary power amplification units 130b1-130bN are close to each other, the load impedance of the main power amplification unit 130a is close to 50/(N+1) ohm, and the load impedance of each of the auxiliary power amplification units 130b1-130bN is close to 50/(N+1) ohm. At this time, the load impedance of the power amplifier system transitions from an initial 50 ohm to the combined impedance of N+1 50/(N+1) ohm in parallel.

In addition to this, the structure of the in-phase synthesizer 200 in the Embodiment 4 is also different from that of Embodiment 1, as shown with reference to FIG. 15. With further reference to FIG. 15, in the Embodiment 4, the in-phase synthesizer 200 includes (N+1) signal input ports 2101-210 (N+1), one signal output port 220, and (N+1) pairs of coupling lines 2301-230 (N+1). The (N+1) pair of coupling lines 2301-230 (N+1) is connected between the (N+1) signal input ports 2101-210 (N+1) and the signal output port 220. Each pair of coupling lines includes a positive coupling line and a negative coupling line. For example, the positive coupling line and the negative coupling line of an ith pair of coupling lines are labeled 230ia and 230ib, respectively, where 1≤i≤N+1. The positive input port and the negative input port of each of the signal input ports are connected to the positive coupling line and the negative coupling line of the corresponding pair of coupling lines.

The signal input port 210i includes a positive input port 210ia and a negative input port 210ib. The positive input port 210ia is connected to the positive coupling line 230ia of the ith pair of coupling lines 230i, and the negative input port 210ib is connected to a negative coupling line 230(i+1)b of an (i+1)th pair of coupling lines 230(i+1). The negative coupling line 230 ib of the ith pair of coupling lines 230i is connected to a positive coupling line 230(i+1)a of the (i+1)th pair of coupling lines 230(i+1), and the connection may be, for example, in series or the like, where 1≤i≤(N+1).

The positive output port 220a and the negative output port 220b of the signal output port 220 are connected to the positive coupling line 2301a of the first pair of coupling lines 2301 and a negative coupling line 230(N+1)b of a (N+1)th pair of coupling lines 230(N+1), respectively.

In order to increase the isolation, in the Embodiment 4, the isolation module may be disposed between the same-polarity ports of different signal input ports, for example, the isolation module is disposed between the positive ports of different signal input ports, or the isolation module is disposed between the negative ports of different signal input ports. The isolation module may include an isolation resistor, or include an isolation resistor and a capacitor that are in a parallel connection.

Further referring to FIG. 15, in order to increase the isolation, an isolation resistor R12a is disposed between the positive input port 2101a of the signal input port 2101 and the positive input port 2102a of the signal input port 2102, the isolation resistor R12b is disposed between the negative input port 2101b of the signal input port 2101 and the negative output port 2102b of the signal input port 2102. In this order, an isolation resistor RN(N+1)a is disposed between a positive input port 210Na of a signal input port 210N and a positive input port 210(N+1)a of a signal input port 210(N+1), and an isolation resistor RN(N+1)b is disposed between a negative input port 210Nb of the signal input port 210N and a negative output port 210(N+1)b of the signal input port 210(N+1).

In some embodiments, as shown in FIG. 14, the power amplifier system further includes the in-phase power divider 300 connected between the input port (RF Input) and the plurality of power amplification branches 100, the in-phase power divider 300 is configured to perform power division on the input signal received from the input port (RF Input) to obtain a plurality of signals of the same phase before output. In some embodiments, the in-phase power divider 300 in Embodiment 3 may adopt a reverse operating mode of the in-phase synthesizer structure shown in FIG. 15. In some embodiments, the in-phase power divider 300 in Embodiment 3 may adopts a reverse operating mode of the in-phase synthesizer structure as illustrated in FIG. 5, FIG. 6, FIG. 10, FIG. 13, or other structural forms of power dividers.

Each of the embodiments in the present disclosure is described in a progressive manner, and it is sufficient to refer to each embodiment for the same and similar portions of each embodiment, and each embodiment focuses on the differences from the other embodiments. In particular, for the power amplifier system or power amplifier system embodiments, the descriptions are simpler because they are substantially similar to the manner embodiments, and it is sufficient to refer to portions of the manner embodiments as relevant. The power amplifier system and the power amplifier system embodiments described above are merely illustrative, the units described as separate components may or may not be physically separated, the components displayed as units may or may not be physical units, i.e., they may be located in one place or distributed across a plurality of network units. Based on actual needs, part or all of the modules may be selected to achieve the purpose of the embodiment scheme. The embodiment may be understood and implemented by a person of skilled in the art without creative labor.

In the description of the present disclosure, reference is made to the terms “an embodiment”, “some embodiments”, “examples”, “specific examples”, or “some examples” means that the specific features, structures, materials, or characteristics described in conjunction with the embodiment or example are included in at least one embodiment or example of the present disclosure. In the present disclosure, the illustrative descriptions of the foregoing terms do not necessarily refer to the same embodiments or examples. And, the specific features, structures, materials, or characteristics described can be combined in any one or more embodiments or examples in a suitable manner.

Additionally, the terms “first,” “second” are used only for descriptive purposes and should not be construed as indicating or implying relative importance, nor as implicitly specifying a count of the technical features referred to. Thus, a feature defined with “first”, “second” may expressly or implicitly include at least one of the features. In the description of the present disclosure, “plurality” is meant to be at least two, e.g., two, three, etc., unless explicitly and specifically limited otherwise.

While embodiments of the present disclosure have been shown and described above, it is to be understood that the above embodiments are exemplary and are not to be construed as a limitation of the present disclosure, and that a person of skilled in the art may make changes, modifications, substitutions, and variations to the above embodiments within the scope of the present disclosure.

What is claimed is:

1. A power amplifier system based on in-phase power synthesis, comprising: an input port, an output port, and a plurality of power amplification branches and an in-phase synthesizer disposed between the input port and the output port, wherein
each of the plurality of power amplification branches is connected to the input port, the plurality of power amplification branches include at least one main power amplification branch and at least one auxiliary power amplification branch, each of the plurality of power amplification branches is configured to amplify an input signal of a same phase received from the input port to obtain an amplified signal; wherein when the at least one auxiliary power amplification branch is in an operating state, a load modulation is performed on the at least one main power amplification branch to reduce a load impedance of the at least one main power amplification branch; and
the in-phase synthesizer is connected between the plurality of power amplification branches and the output port, the in-phase synthesizer is configured to perform power synthesis on the amplified signal at the same phase output from each of the plurality of power amplification branches to obtain a synthesized output signal, and transmit the synthesized output signal to the output port for output.

2. The power amplifier system of claim 1, wherein each of the plurality of power amplification branches includes:
a power amplification unit configured to amplify the input signal of the same phase received from the input port for one of the plurality of power amplification branches in which the power amplification unit is located; and
an impedance conversion network connected to the power amplification unit, configured to perform the load modulation of the power amplification unit of one of the plurality of power amplification branches in which the impedance conversion network is located.

3. The power amplifier system of claim 2, wherein a type of a power amplification unit used in the at least one main power amplification branch is different from a type of a power amplification unit used in the at least one auxiliary power amplification branch.

4. The power amplifier system of claim 2, wherein when an output power of the power amplifier system is less than a first threshold, the at least one main power amplification branch is in the operating state, and the at least one auxiliary power amplification branch is in an off state.

5. The power amplifier system of claim 4, wherein when the output power of the power amplifier system is not less than the first threshold, the at least one auxiliary power amplification branch is in the operating state.

6. The power amplifier system of claim 5, wherein when the at least one auxiliary power amplification branch is in the operating state, the load modulation is performed on the at least one main power amplification branch to reduce the load impedance of the at least one main power amplification branch including:
when the at least one auxiliary power amplification branch in the operating state, the at least one auxiliary power amplification branch performing the load modulation of the at least one main power amplification branch to reduce the load impedance of the at least one main power amplification branch until a difference between the load impedance of the at least one main power amplification branch and a load impedance of the at least one auxiliary power amplification branch is less than a second threshold.

7. The power amplifier system of claim 6, wherein an initial load impedance of the at least one main power amplification branch is ZC, a count of the at least one auxiliary power amplification branch is N, and when the load impedance of the at least one main power amplification branch is reduced to be equal to the load impedance of the at least one auxiliary power amplification branch, the load impedance of the at least one main power amplification branch becomes ZC/(N+1).

8. The power amplifier system of claim 2, wherein the impedance conversion network includes a first capacitor, a second capacitor, a first coupling line, and a second coupling line; wherein
a first end of the first capacitor and a first end of the first coupling line are connected to a first input port of the impedance conversion network, and a first end of the second capacitor and a first end of the second coupling line are connected to a second input port of the impedance conversion network, respectively; and
a second end of the second capacitor and a second end of the first coupling line are connected to a first output port of the impedance conversion network, and a second end of the first capacitor and a second end of the second coupling line are connected to a second output port of the impedance conversion network, respectively.

9. The power amplifier system of claim 1, wherein the in-phase synthesizer includes a plurality of signal input ports, a signal output port, and M pairs of coupling lines connected between the plurality of signal input ports and the signal output port; wherein a positive input port and a negative input port of at least one of the plurality of signal input ports are connected to a positive coupling line and a negative coupling line of different pairs of coupling lines, respectively, and M is equal to a count of the plurality of power amplification branches.

10. The power amplifier system of claim 9, wherein the plurality of signal input ports of the in-phase synthesizer are not isolated from each other.

11. The power amplifier system of claim 9, wherein an isolation module is disposed between at least two of the plurality of signal input ports of the in-phase synthesizer.

12. The power amplifier system of claim 1, wherein the in-phase synthesizer includes a plurality of signal input ports, a signal output port, and M pairs of coupling lines connected between the plurality of signal input ports and the signal output port; wherein a positive input port and a negative input port of each of the plurality of signal input ports are connected to a positive coupling line and a negative coupling line of a corresponding pair of coupling lines, respectively, and M is equal to a count of the plurality of power amplification branches.

13. The power amplifier system of claim 12, wherein an isolation module is disposed between at least two of the plurality of signal input ports of the in-phase synthesizer.

14. The power amplifier system of claim 1, further comprising:
an in-phase power divider connected between the input port and the plurality of power amplification branches, configured to perform power division on the input signal received from the input port to obtain a plurality of signals of the same phase before output.

15. The power amplifier system of claim 1, wherein each of the plurality of power amplification branches further includes at least one of an input impedance matching circuit located on a signal input side of the power amplification unit or an output impedance matching circuit located on a signal output side of the power amplification unit.
